(19) United States
(12) Patent Application Publication
(10) Pub. No.: US 2015/0165504 A1
(43) Pub. Date: Jun. 18, 2015

(54) REINFORCEMENT METHOD, AND TURRET PUNCH PRESS APPARATUS

(71) Applicant: FUJITSU LIMITED, Kawasaki-shi (JP)

(72) Inventor: Naomi Fukunaga, Kawasaki (JP)

(21) Appl. No.: 14/546,093

(22) Filed: Nov. 18, 2014

(30) Foreign Application Priority Data
Dec. 13, 2013 (JP) 2013-258671

(51) Int. Cl. B21D 22/02; H05K 7/14

(52) U.S. Cl. CPC B21D 22/02; H05K 7/1488

(57) ABSTRACT

A reinforcement method includes: pressing a punch against a plate material from an opposite side to a die body to form a reinforcing portion on the plate material, wherein the punch includes a wedge projection which is provided in flank of a reinforcing portion forming portion extending along a relative movement direction of the die body and in parallel with the reinforcing portion forming portion, and is longer than a length of the relative movement direction of the die body.

### CROSS-REFERENCE TO RELATED APPLICATION

This application is based upon and claims the benefit of priority from the prior Japanese Patent Application No. 2013-258671 filed on Dec. 13, 2013, the entire contents of which are incorporated herein by reference.

### FIELD

The emobdiments discussed herein are related to a reinforcement method of a chassis, and a turret punch press apparatus.

### BACKGROUND

It is requested to achieve high performance of electronic devices and miniaturization and densification of electronic devices. In order to arrange, for example, an electric unit including a printed circuit board or a connection cable in a limited space, a high strength and space-saving chassis or outer frame is requested. A plurality of devices is stacked in a rack in a server apparatus. Therefore, when a chassis is distorted or bent, the devices may interfere with each other, and thus, stacking of the devices is disturbed. A measure for providing strength such as, for example, addition of a bending processing, addition of a reinforcement element, or thickening may inhibit space saving.

A related technique is disclosed in Japanese Laid-Open Patent Publication No. 08-276225.

### SUMMARY

According to one aspect of the embodiments, a reinforcement method includes: pressing a punch against a plate material from an opposite side to a die body to form a reinforcing portion on the plate material, wherein the punch includes a wedge projection which is provided in flank of a reinforcing portion forming portion extending along a relative movement direction of the die body and in parallel with the reinforcing portion forming portion, and is longer than a length of the relative movement direction of the die body.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a view illustrating an exemplary turret punch press apparatus;

FIG. 2 is a block diagram illustrating an exemplary turret punch press apparatus;

FIG. 3 is a view illustrating an exemplary server device accommodated in a rack;

FIG. 4 is an exemplary exploded perspective view of a server device;

FIG. 5 is a view illustrating an exemplary punch, an exemplary die body and an exemplary die holder of a turret punch press apparatus;

FIG. 6 is a view illustrating an exemplary surface on which wedge projections of a punch are formed;

FIG. 7 is a view illustrating an exemplary punch and an exemplary die body;

FIG. 8 is a view illustrating an exemplary state where a punch and a die body are combined;

FIG. 9 is a view illustrating an exemplary wedge projection;

FIG. 10 is a view illustrating an exemplary state of a processed plate material;

FIGS. 11A to 11D are views illustrating an exemplary processing method using the turret punch press apparatus;

FIGS. 12A and 12B are views illustrating an exemplary formation of a bead and long grooves;

FIG. 13A is a view illustrating an exemplary bead and exemplary long grooves;

FIG. 13B is a view illustrating an exemplary warpage amount of a plate material;

FIG. 14A is a view illustrating an exemplary bead and exemplary long grooves;

FIG. 14B is a view illustrating an exemplary warpage amount of a plate material;

FIG. 15 is an exemplary perspective view illustrating an exemplary plate material;

FIGS. 16A and 16B are views illustrating an exemplary distribution of Mises stresses;

FIGS. 17A to 17C are views illustrating an exemplary processing; and

FIGS. 18A to 18C are views illustrating an exemplary processing method using a turret punch press apparatus.

### DESCRIPTION OF EMBODIMENTS

In order to secure space saving and strength of a device, a plate material is processed to form a bead on a chassis. A method for forming the bead on the plate material includes, for example, a press processing using a dedicated mold and a press machine. The press processing using a dedicated mold may not be adopted in a case where preparation of the mold requires labor and a certain amount of production is not expected.

A numerically controlled turret (NCT) processing using an NCT punch press apparatus may be suitable for small production. Since a desired shape is obtained by a repetitive punch operation, the NCT processing is highly versatile and is easily applicable to a small quantity production. In the NCT processing, processing distortion may occur. Since the distortion is accumulated by the repetitive punch operations to cause a plate material serving as a workpiece to be processed to be warped, the NCT processing may not be suitable for chassis of electronic devices which are stacked.

When, for example, a press processing is performed on a metal, suppression of deformation of a workpiece would be an issue. For example, a blank holding method may be provided in a drawing processing using a press machine.

For example, the blank holding method may reduce the generation of wrinkles when the drawing processing is performed. The blank holding method may not be employed in the NCT processing using the turret punch press apparatus.

In a reinforcement method of a chassis, warpage of the chassis may be reduced when a groove-shaped reinforcing portion is formed on the chassis using the turret punch press apparatus.

The dimension and ratio of each part illustrated in the drawings may not completely coinside with those of an actual one.

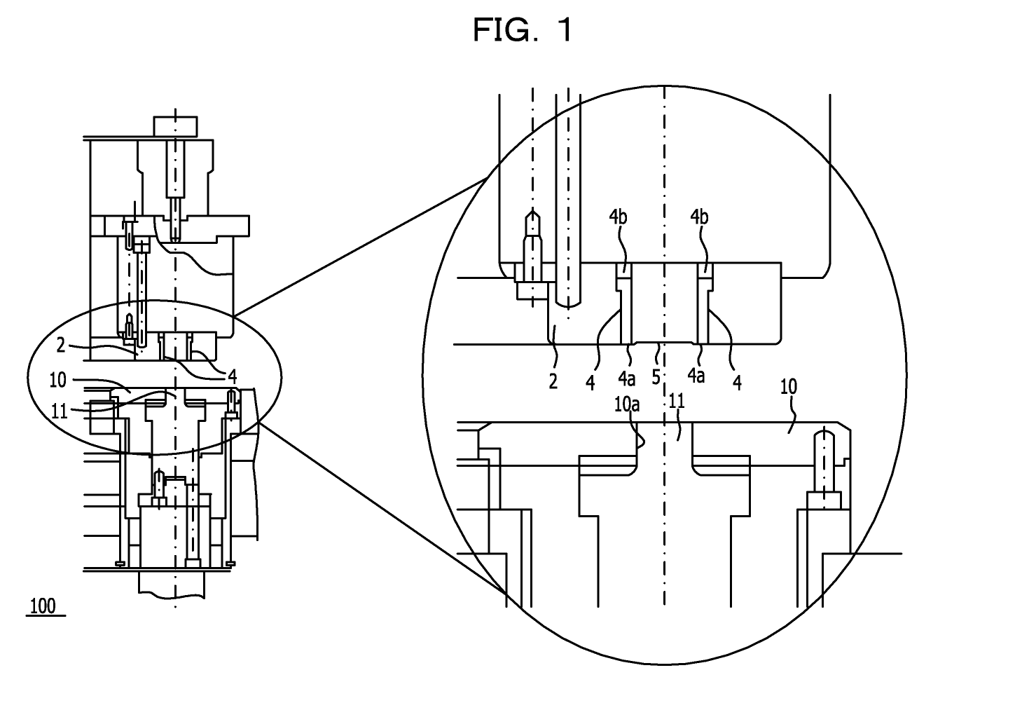

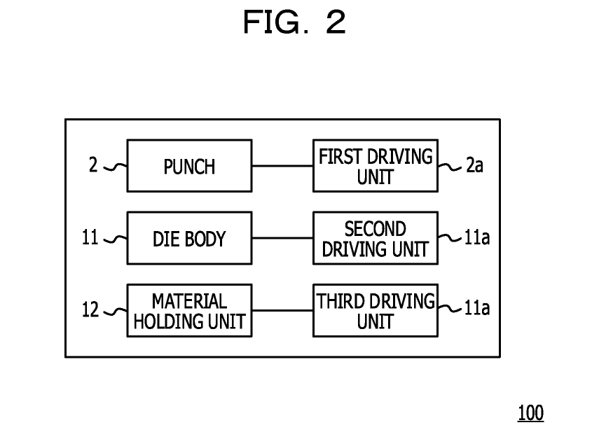

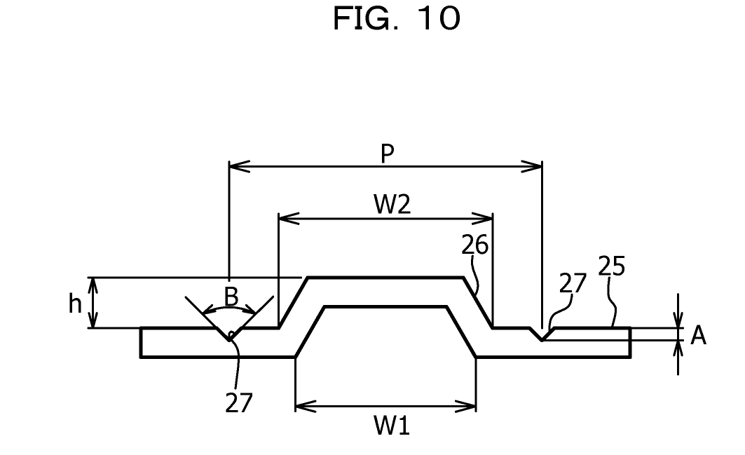

FIGS. 1 and 2 illustrate an exemplary turret punch press apparatus. FIG. 1 illustrates a schematic configuration of a turret punch press apparatus (hereinafter, referred to as an “NCT apparatus”) 100. FIG. 2 is a block diagram illustrating a main part of the NCT apparatus 100. The NCT apparatus 100 may execute a reinforcement method of a chassis where, while relatively moving a plate material 25, which may be a workpiece to be processed or become a chassis, and a die body 11, a groove-shaped bead 26 (see, for example, FIG. 10) is formed along the relative movement direction of the die body 11. In performing the reinforcement method of the chassis, when the die body 11 is pressed against the plate material 25 to form the bead 26, the NCT apparatus 100 presses a punch 2 against the plate material 25 from an opposite side to the die body 11. The punch 2 is provided with a reinforcing portion forming portion 5 extending along the relative movement direction of the die body 11 and wedge projections 4a which is provided in flank of the reinforcing portion forming portion 5 and in parallel with the reinforcing portion forming portion 5 and is longer than the length of the die body 11 in the relative movement direction.

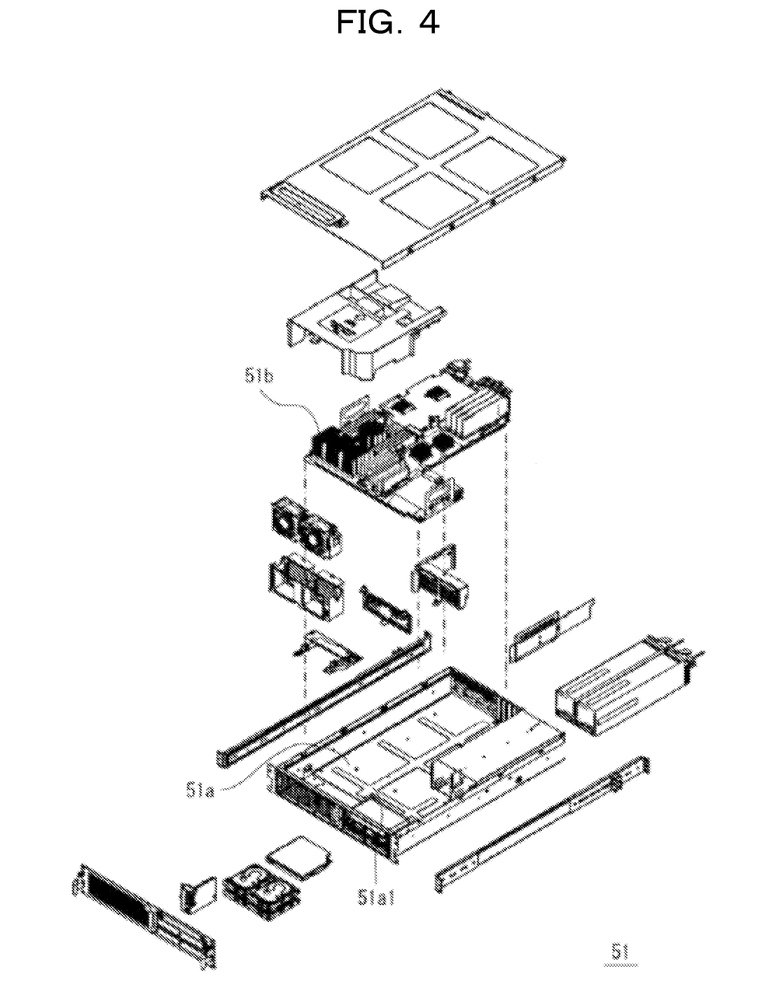

The NCT apparatus 100 may be a numerically controlled press machine. For example, the NCT apparatus 100 is provided with the punch 2 and the die body 11 which is held in a die holder 10 and disposed to face the punch 2. The die body 11 is accommodated and supported in a die body accommodating portion 10a, which is provided in the die holer 10, to be projectable to and retractable from the punch 2 side. The punch 2 is driven by a first driving unit 2a. The die body 11 is driven by a second driving unit 11a. The NCT apparatus 100 is provided with a material holding unit 12 configured to hold the plate material 25 which may be a workpiece to be processed or correspond to a chassis 51a (see, for example, FIG. 4). The material holding unit 12 is driven by a third driving unit 12a to move the plate material 25 at a desired pitch in a desired dirction. Thereofere, the material holding unit 12 changes relative positions of the plate material 25 and the die body 11, and in turn, changes the position of the plate material 25 which is pressed by the punch 2 and the die body 11.

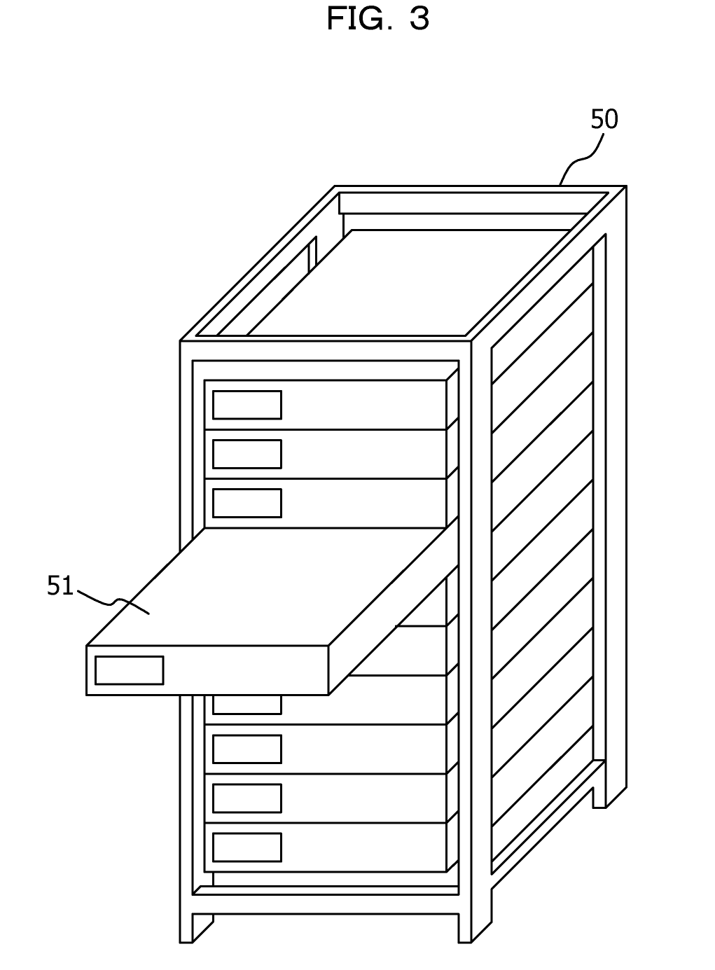

The NCT apparatus 100 forms a desired bead 26 (see, for example, FIG. 10) on the plate material 25. The bead 26 is formed as a reinforcing portion 51a1 in a desired shape by gradually shifing a hit point of the die body 11 to be partially overlapping, and successively shaping the bead 26. FIG. 3 illustrates an exemplary server device accommodated in a rack. FIG. 4 is an exemplary exploded perspective view of the server device. The plate material 25 may be applied to any product. For example, the plate material 25 may be used as a material for a chassis 51a of a server device 51 as illustrated in FIGS. 3 and 4, and may be formed with the reinforcing portion 51a1 to reinforce the chassis 51a. A plurality of server devices 51 may be stacked in a rack 50 as illustrated in FIG. 3. Thus, when the chassis 51a is warped during the processing or bent due to a heavy load, the stacking may be disturbed. Therefore, the reinforcing portion 51a1 is provided while reducing the warpage when processing the chassis 51a. The reinforcing portion 51a1 may be disposed appropriately as necessary, or may be provided, for example, at a place where a motherboard 51b is mounted as a heavy load.

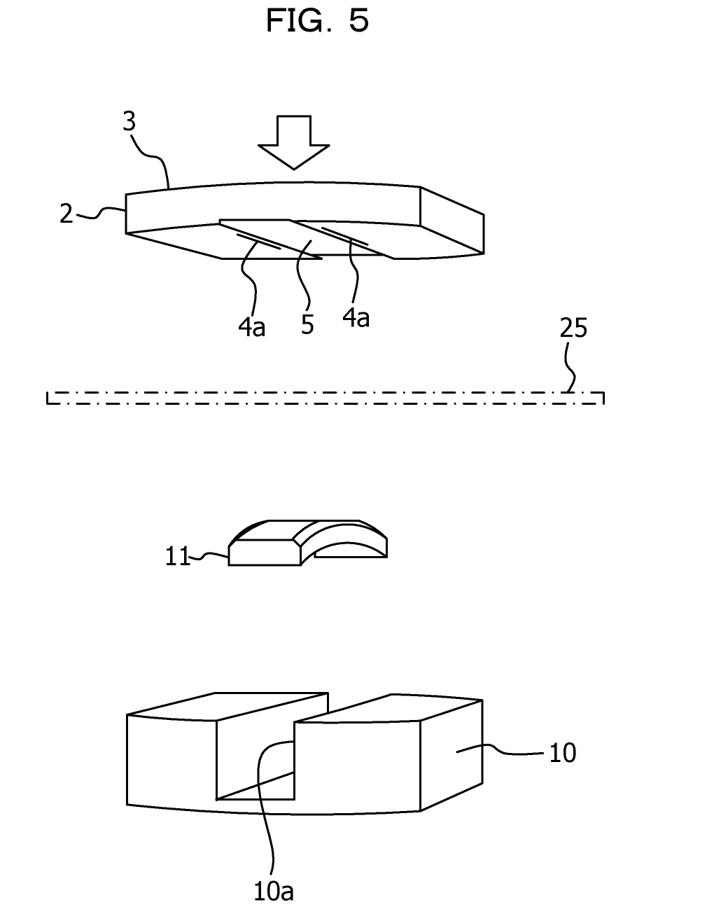

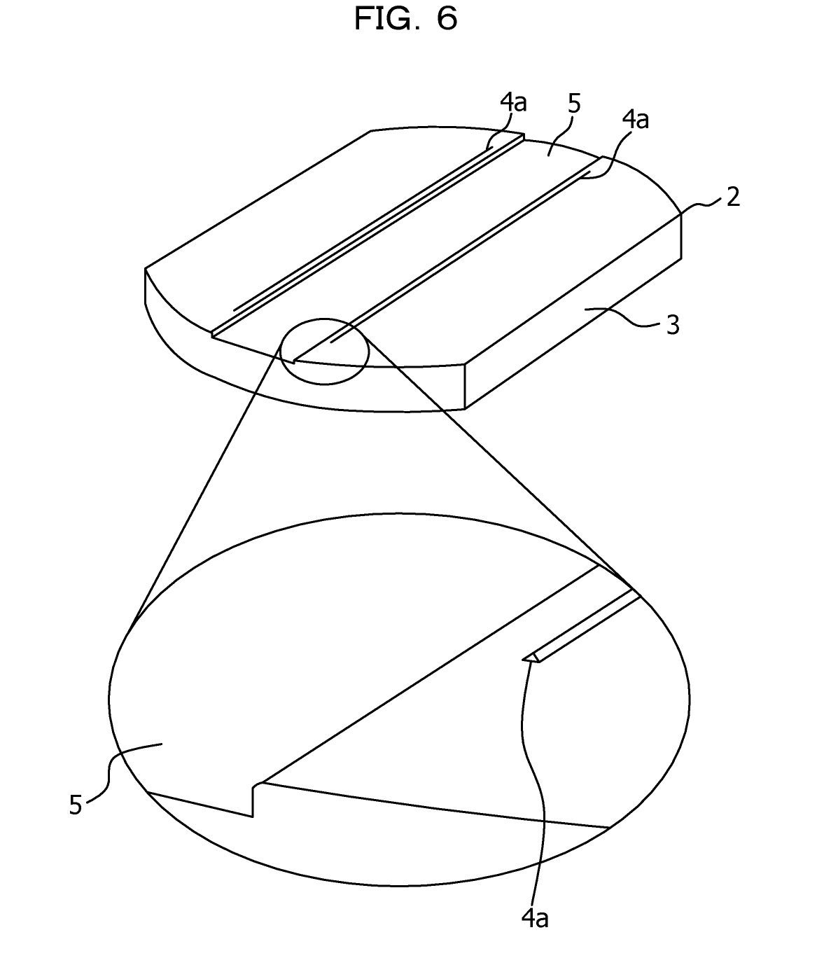

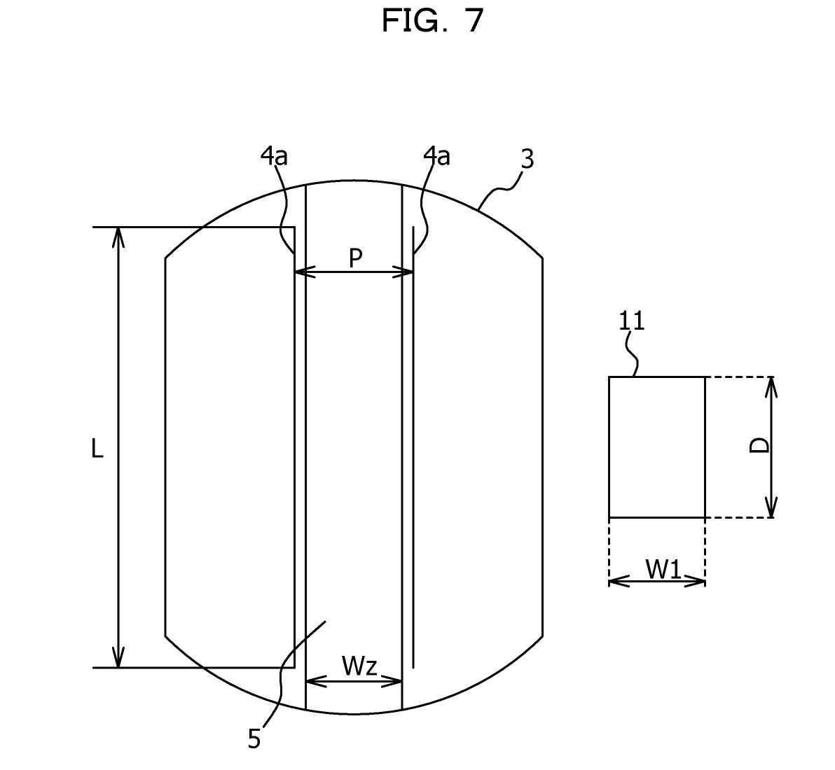

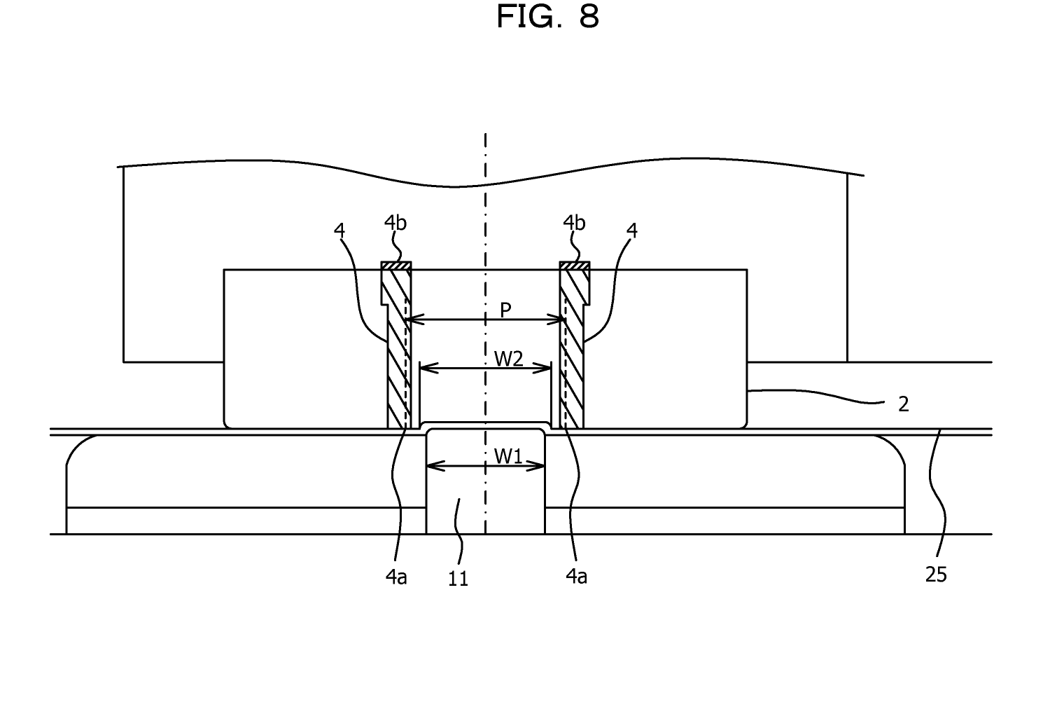

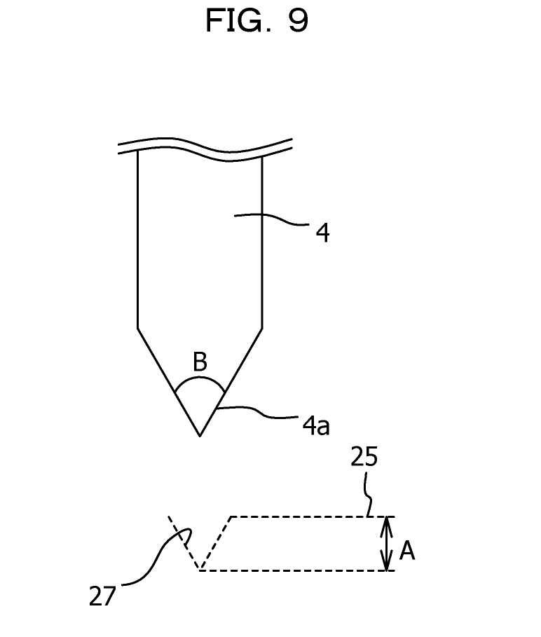

FIG. 5 illustrates an exemplary punch, an exemplary die body and an exemplary die holder of a turret punch press apparatus. FIG. 6 illustrates an exemplary surface on which wedge projections of a punch are formed. FIG. 7 illustrates an exemplary punch and an exemplary die body. FIG. 8 illustrates an exemplary state where a punch and the die body are combined. FIG. 9 illustrates an exemplary wedge projection. FIG. 10 illustrates an examplary state of a processed plate material. The punch 2 illustrated in FIG. 5 is provided with a reinforcing portion forming portion 5 extending along a relative movement direction of the die body 11 with respect to the plate material 25, and wedge projections 4a which is provided in flank of the reinforcing portion forming portion 5 and in parallel with the reinforcing portion forming portion 5. For example, the punch 2 is provided with a plate-like punch chip 3 and two wedge chips 4 embedded in the punch chip 3. The reinforcing portin forming portion 5 may be groove-shaped, and provided on a surface facing the plate material 25. For example, in the reinforcing portion forming portion 5, a bead 26 illustrated in FIG. 10 is formed by pressing the plate material 25 against the punch 2 side by the die body 11. The length L of each wedge projection 4a may be longer than the length D along the relative movement direction of the die body 11. The width of the reinforcing portion forming portion 5 is set to W2 as illustrated in FIG. 7. The width W2 of the reinforcing portion forming portion 5 may correspond to a width of a convex side, for example, an outer side of the bead 26. The depth of the reinforcing portion forming portion 5 is denoted as “h”.

Each wedge chip 4 is formed with a wedge projection 4a at an edge thereof as illustrated in an enlarged scale in FIG. 6. Each wedge procjection 4a is exposed on a surface where the reinforcing portion forming portion 5 of the punch chip 3 is provided. For example, the wedge projections 4a are provided on the surface (facing the plate material 25) of the punch 2 which is disposed to face the die body 11. The wedge projections 4a are provided at both sides of the reinforcing portion forming portion 5 and in parallel with the reinforcing portion forming portion 5. A distance between the two wedge projections 4a disposed in parallel with each other as illustrated in FIG. 7 is denoted as P. The two wedge projections 4a extend along the relative movement direction between the plate material 25 serving as the workpiece and the die body 11. The length of each wedge projection 4a extending along the relative movement direction is denoted as L. The wedge chips 4 are formed with shims 4b at the ends opposite to the wedge projections 4a, respectively. The projection amount of the wedge projections 4a may be changed as the number of shims 4b is changed. As the projection amount of the wedge projections 4a is changed, the depth A of long grooves 27 (see, for example, FIGS. 9 and 10) carved on the surface of the plate material 25 by the wedge projections 4a is adjusted. As illustrated in FIG. 9, the angle of a tip end of the wedge projection 4a is denoted as B. The angle B is changed by exchanging the wedge chip 4 with one having a desired tip angle.

The width of the die body 11 is set to W1 as illustrated in FIG. 7. The width W1 of the die body 11 may correspond to a width of a concave side, for example, an inner side of the bead 26. The length in which the die body 11 and the plate material 25 of the die body 11 extend along the relative movement is denoted as D. Comparing the length D of the die body 11 and the length L of the wedge projections 4a, the length L of the wedge projections 4a is longer. Therefore, when the bead 26 is formed, stress generated in the bead forming process may not be propagated to an outer region of the wedge projections 4a and the long grooves 27 which is formed by the wedge projections 4a.

When the bead 26 is formed by pressing the die body 11 against the plate material 25, the punch 2 is pressed aganst the plate material 25 form an opposite side to the die body 11. The punch 2 is provided with the reinforcing portion forming portion 5 and the wedge projections 4a, and the bead 26 may be formed while reducing the inner stress of the plate material 25. For example, the plate material 25 is processed in a shape as illustrated in FIG. 10 by operating the NCT apparatus 100 provided with the punch 2 and the die body 11. For example, when observing a cut section, the bead 26 is formed to have an inner diameter width W1, an outer diameter width W2 and a height h. When the bead 26 is formed, the wedge-shaped long grooves 27 having a depth A and an angle B are formed at both sides of the bead 26. Since the bead 26 is formed, the strength of the plate material 25 may be enhanced. When the bead 26 is formed, the wedge projections 4a are pressed against the plate material 25 such that propagation of the stress is suppressed, thereby reducing the warpage amount of the plate material 25. For example, in the bead forming process, the plate material 25 falls into a non-uniform internal stress state where compression and tension are mixed, and when an external force is removed thereafter, the internal stress is released such that warpage may occur in the plate material 25. For example, in the NCT processing, since the bead forming operations are performed repeatedly, warpage occurs in every operation and the warpage is accumulated so that the warpage amount may be increased. In a case where the warpage occurring in every bead forming operation by the press is decreased, when the bead 26 is formed in a desired shape, the whole warpage amount is reduced. The bead 26 is subjected to a processing by the die body 11 and the punch 2 while relatively moving the plate material 25 to form a reinforcing portion 51a1 in a desired shape.

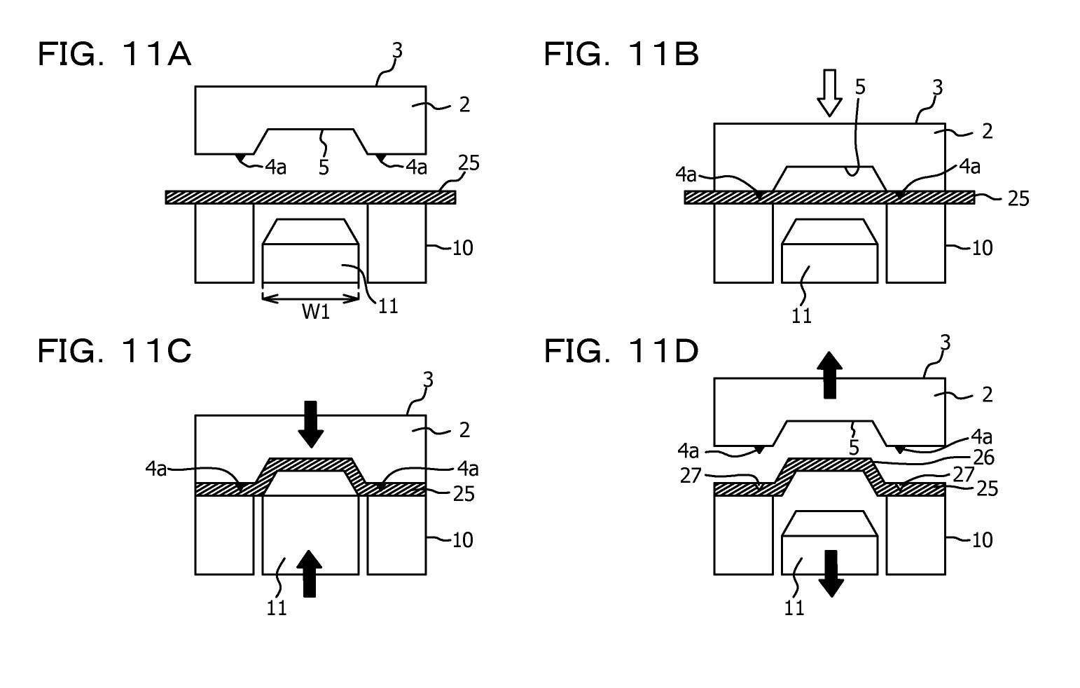

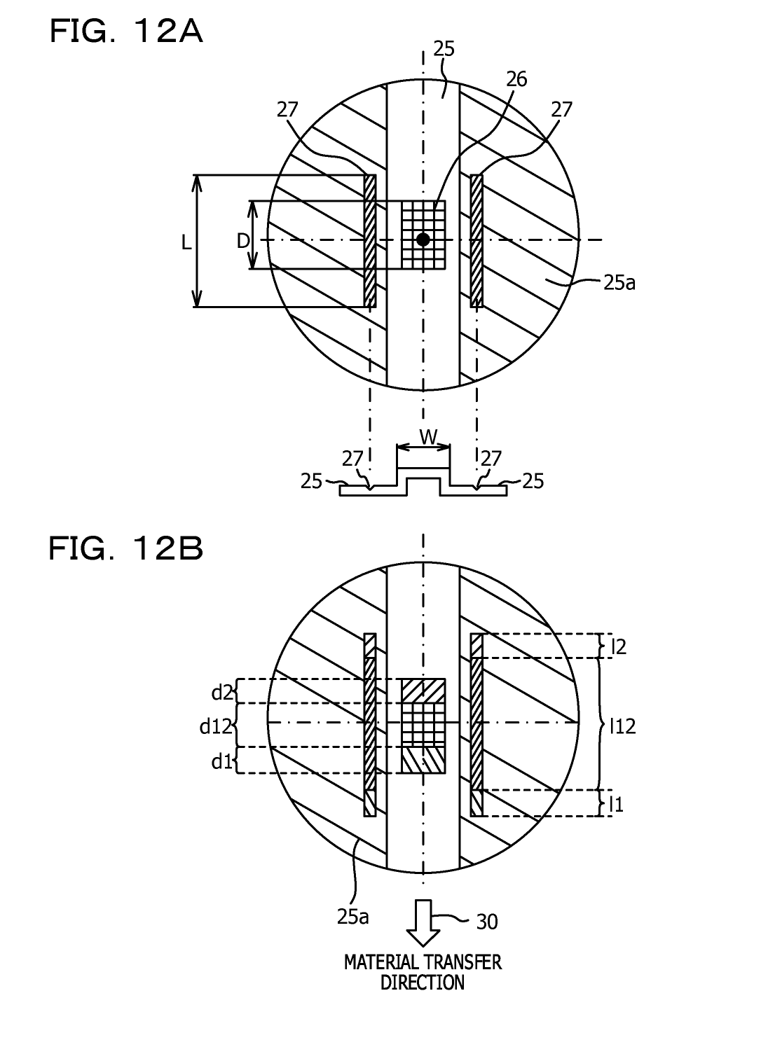

The operation timing of the punch 2 and the die body 11 may be a timing capable of pressing the wedge projections 4a against the plate material 25 such that the stress is not propagated during the bead formation. FIGS. 11A to 11D illustrate an exemplary processing method using a turret punch press apparatus. FIGS. 12A and 12B illustrate an exemplary formation of a bead and a long grooves. In FIGS. 12A and 12B, the bead and the long grooves are sequentially formed by the forming operation of the punch and the die body. For example, the punch 2 and the die body 11 may be operated at a timing as illustrated in FIGS. 11A to 11D. As illustrated in FIG. 11A, the plate material 25 is provided on the die holder 10 such that a processing site of the plate material 25 faces the reinforcing portion forming portion 5 and the die body 11. As illustrated in FIG. 11B, the punch 2 moves down and pushes the plate material 25. Thereofore, the wedge projections 4a is pressed against the plate material 25, and bites into the surface of the plate material 25. As a result, long grooves 27 are formed in flank of a position where the bead 26 of the plate material 25 is formed, extends along the relative movement direction of the die body 11 and is longer than the length along the relative movement direction of the die body 11. As illustrated in FIG. 11C, the elevated die body 11 pushes the plate material 25. The stress generated in the plate material 25 when the plate material 25 is bent is suppressed from propagating outside the wedge projections 4a. Then, as illustrated in FIG. 11D, the punch 2 and the die body 11 are separated from the plate material 25. At this time, the plate material 25 may be in a state as illustrated in FIG. 12A. For example, the plate material 25 is formed with a bead 26 having a length D, and long grooves 27 having a length L are carved at both sides of the bead 26 to be in parallel therewith. Even though the external force applied to the plate material in such a state is released, the propagation of the internal stress is suppressed, and thus, warpage is suppressed from occurring in the whole plate material 25. After the punch 2 and the die body 11 are separated from the plate material 25, the plate material 25 is sent at a desired pitch in a direction indicated by an arrow 30 in FIG. 12B. The operations of FIGS. 11B to 11D are repeated. After the second forming operation is completed, the plate material 25 may be in a state as illustrated in FIG. 12B. For example, the plate material 25 is moved in the direction indicated by the arrow 30, and thus, the plate material 25 and the die body 11 are relatively moved. As the bead forming operation is performed, the bead 26 having a length d1 provided in the first forming operation plus a length d12 is further lengthened by a length d2 by the second forming operation. The length d12 may be the length of a portion in which the die body 11 is overlapped. Likewise, the long grooves 27 having a length l1 provided in the first forming operation plus a length l12 are further lengthened by a length l2 by the second forming operation. The length l12 may be the length of a portion in which the wedge projections 4a are overlapped. As the forming operations are repeated necessary number of times, the bead 26 and the long grooves 27 extend. Although the repetitive forming operations are performed, the warpage caused by one forming operation is reduced. Therefore, even after the repetitive forming operations are performed and the bead 26 is formed in a desired shape, the plate material 25 may be obtained while suppressing warpage. When the forming operation is performed, in the plate material 25, the region denoted by a reference numeral 25a illustrated in FIGS. 12A and 12B is pushed. For example, since the flank of the bead 26 is pushed extensively, the plate material 25 may be suppressed from sliding.

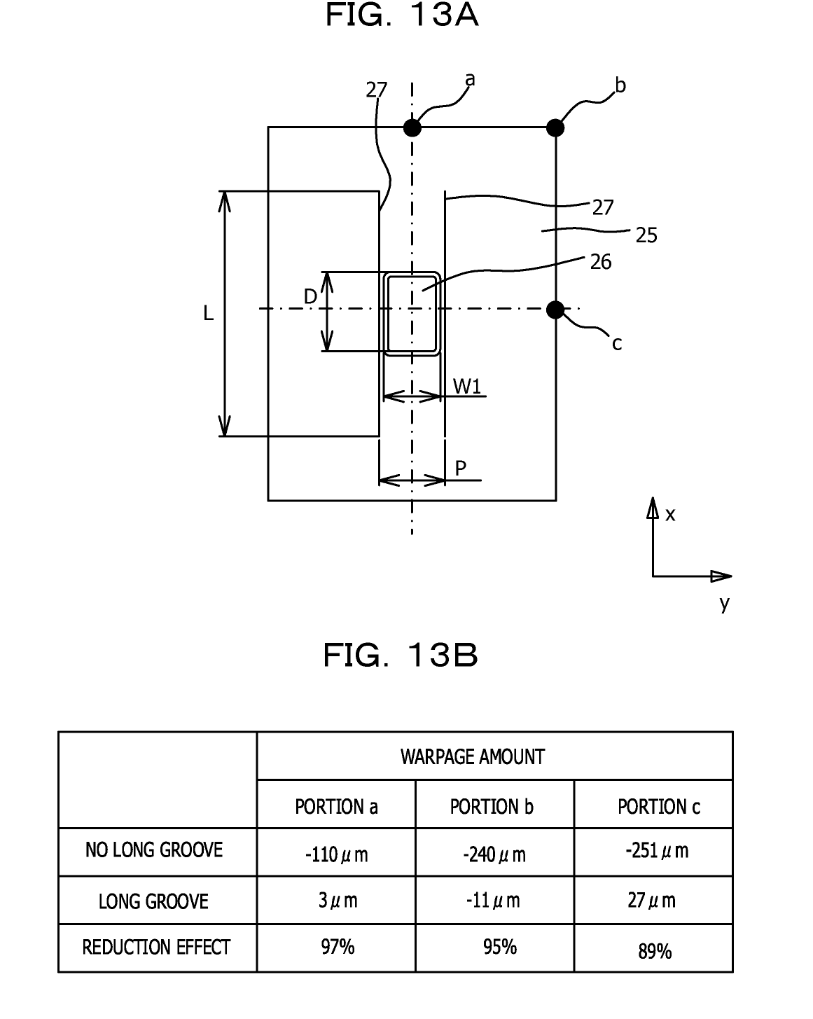

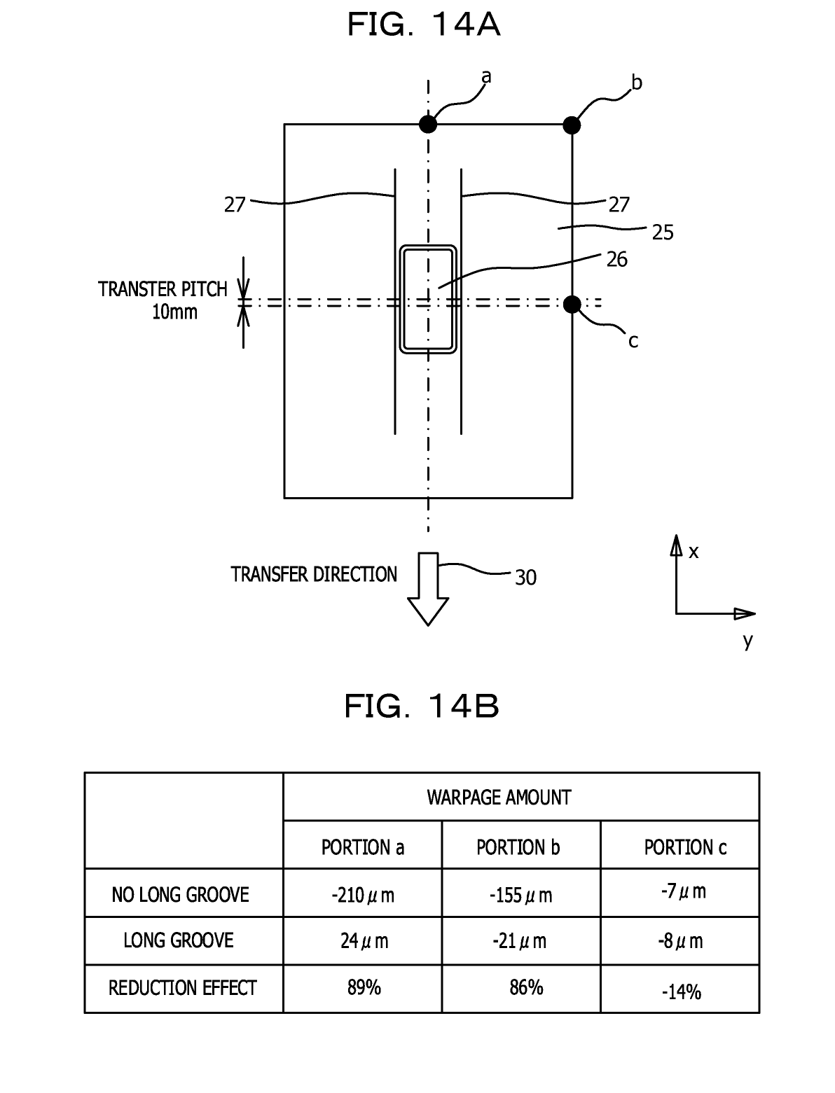

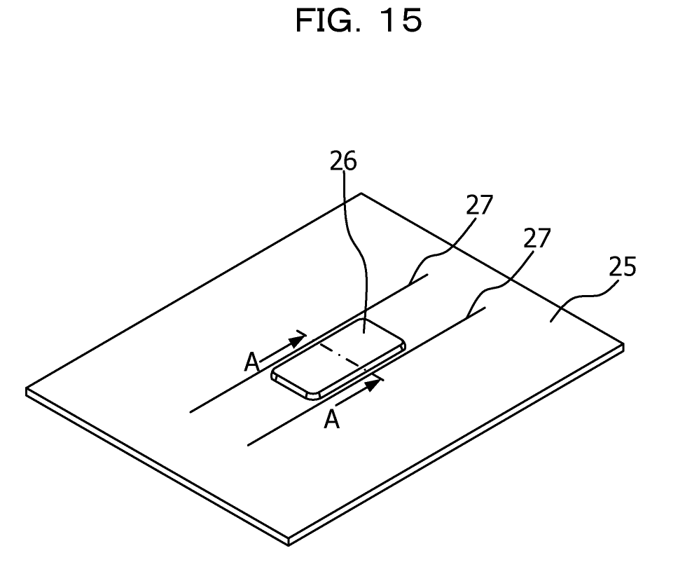

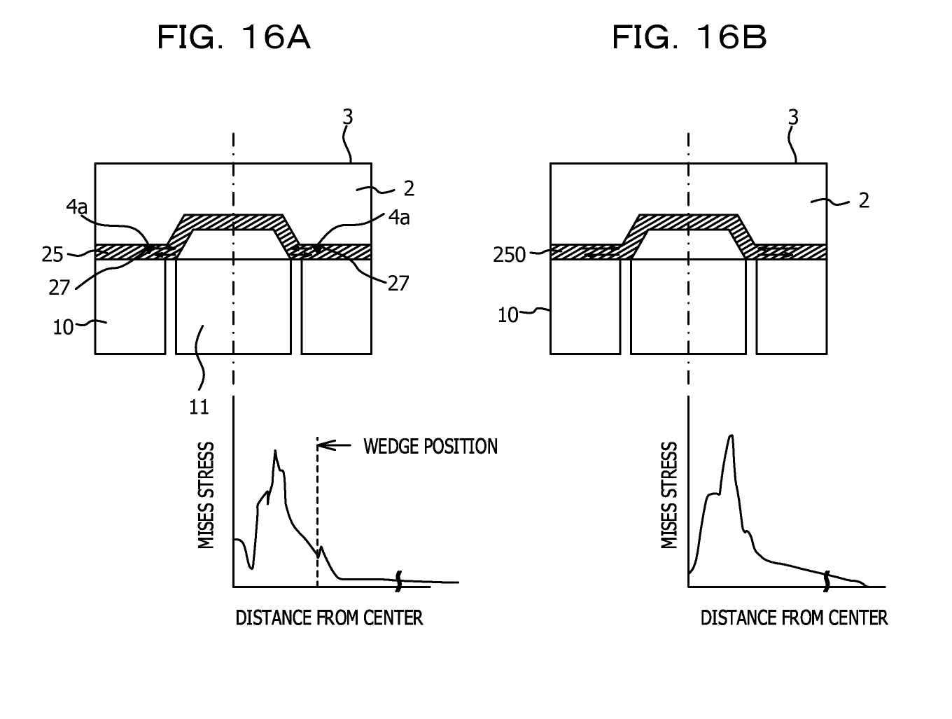

FIG. 13A illustrates an exemplary bead and exemplary long grooves. In FIG. 13A, the bead 26 and the long grooves 27 formed by performing the bead forming operation once are illustrated. FIG. 13B illustrates an exemplary warpage amount of a plate material. Table in FIG. 13B represents the difference in warpage amount of the plate material 25 depending on the presence or absence of the long grooves 27. FIG. 14A illustrates an exemplary bead and exemplary long grooves. In FIG. 14A, the bead 26 and the long grooves 27 formed by performing the bead forming operation twice are illustrated. FIG. 14B illustrates an exemplary warpage amount of a plate material. Table in FIG. 14B represents the difference in warpage amount of the plate material 25 depending on the presence or absence of the long grooves 27. FIG. 15 illustrates an exemplary plate material. In FIG. 15, a perspective view of the plate material 25 formed with a bead 26 and long grooves 27, is illustrated. FIGS. 16A and 16B illustrate an exemplary distribution of Mises stresses. FIG. 16A illustrates the distribution of the Mises stress in a cross-section along a line A-A in FIG. 15.

For example, the processing conditions may be as follows. As the plate material 25, an electro-galvanized steel sheet (SECC) having a thickness of 1 mm is used. The die body 11 may have a length D=30 mm and a width W1=20 mm. Each wedge projection 4a may have a length L=90 mm, a pitch P=24 mm, and a depth A=0.1 mm. A punch pressing load is set to 10 tons. A friction coefficient of the contact surface of the plate material 25 may be 0.15. The measurement points are set at three points, for example, a portion “a”, a portion “b” and a portion “c”, which are designated by x- and y-coordinates from the central point of the bead 26. The coordinate of the portion “a” is assumed as (x, y)=(0 mm, 70 mm). The coordinate of the portion “b” is assumed as (x, y)=(54 mm, 70 mm). The coordinate of the portion “c” is assumed as (x, y)=(54 mm, 0 mm).

In an evaluation after the bead forming operation is performed once, comparison may be made between a case where the long grooves 27 are present and a case where the long grooves 27 are absent. In the notation of the warpage amount, the symbols ‘+ (plus)’ and ‘− (minus)’ indicate that warpage occurs oppositely. At the portion “a” after the bead forming operation is performed once, the warpage amount without the long grooves 27 is −110 μm, and the warpage amount with the long grooves 27 is 3 μm. Therefore, the reduction effect of the warpage amout may be evaluated as 97% as calculated from (110−3) (μm)/110 (μm). At the portion “b”, the warpage amount without the long grooves 27 is −240 μm, and the warpage amount with the long grooves 27 is −11 μm. Therefore, the reduction effect of the warpage amout may be evaluated as 95% as calculated from (240−11) (μm)/240 (μm). At the portion “c”, the warpage amount without the long grooves 27 is −251 μm, and the warpage amount with the long grooves 27 is 27 μm. Therefore, the reduction effect of the warpage amout may be evaluated as 89% as calculated from (251−27) (μm)/251 (μm).

In an evaluation after the bead forming operation is performed twice, comparison may be made between a case where the long grooves 27 are present and a case where the long grooves 27 are absent. At the portion “a” after the bead forming operation is performed twice, the warpage amount without the long grooves 27 is −210 μm, and the warpage amount with the long grooves 27 is 24 μm. Therefore, the reduction effect of the warpage amout may be evaluated as 89% as calculated from (210−24) (μm)/210 (μm). At the portion “b”, the warpage amount without the long grooves 27 is −155 μm, and the warpage amount with the long grooves 27 is −21 μm. Therefore, the reduction effect of the warpage amout may be evaluated as 86% as calculated from (155−21) (μm)/155 (μm). At the portion “c”, the warpage amount without the long grooves 27 is −7 μm, and the warpage amount with the long grooves 27 is −8 μm. Therefore, the reduction effect of the warpage amout may be evaluated as −14% as calculated from (8−7) (μm)/7 (μm). At the portion “c” immediately after the bead forming operation is performed twice, the warpage amount is slightly increased. However, since the warpage amount itself is very little, it may be evaluated that the warpage amount is reduced.

As for the Mises stress in the A-A cross-section as illustrated in FIG. 15, comparison may be made between a case where the long grooves 27 are present as illustrated in FIG. 16A and a case where the long grooves 27 are absent as illustrated in FIG. 16B. In the plate material 25 as illustrated in FIG. 16B, the Mises stress is present even in the outside of the bent portions, and gradually reduced outwards. In the plate material 25 as illustrated in FIG. 16A, the Mises stress is sharply reduced from the positions of the wedge projections 4a towards the outside. Therefore, even though an external force applied to the plate material 25 is removed, the generation of the warpage may be suppressed.

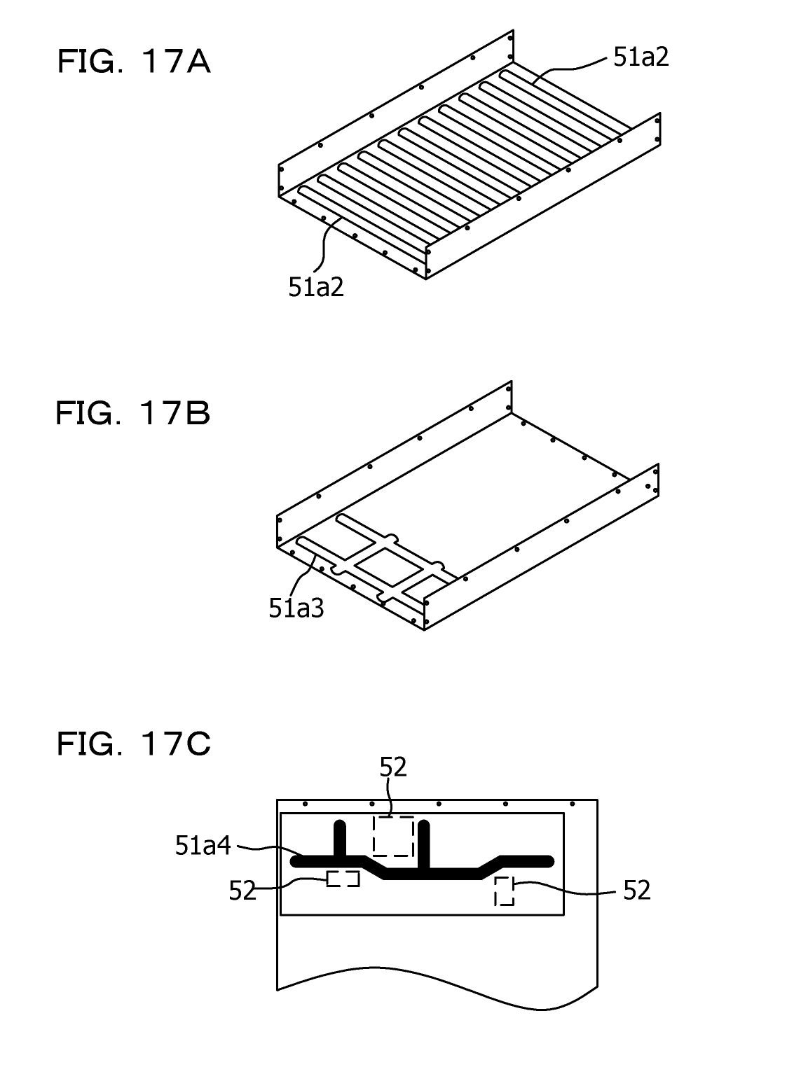

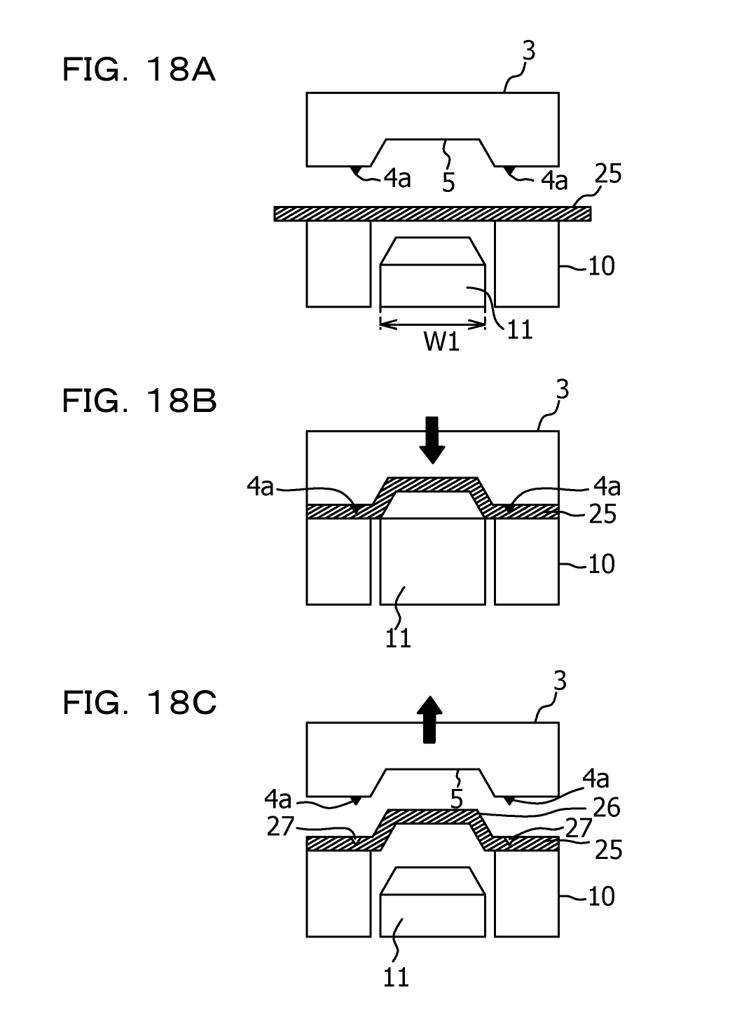

In the reinforcement method of a chassis, the bead 26 may be formed while suppressing the warpage of the plate material 25. In the reinforcement method of a chassis, since the NCT apparatus 100 is used, it is easy to form a reinforcing portion in which the bead 26 is arranged in a desired shape. FIGS. 17A to 17C illustrates an exemplary processing. FIGS. 18A to 18C illustrates an exemplary processing method using a turret punch press apparatus. For example, as illustrated in FIG. 17A, a reinforcing portion 51a2 may be formed in a linear shape to be provided in parallel. As illustrated in FIG. 17B, a reinforcing portion 51a3 may be formed to be provided in a grid pattern. As illustrated in FIG. 17C, a reinforcing portion 51a4 may be formed in a complicated shape in order to avoid electronic parts 52.

An operation timing of the punch 2 and the die body 11 may be a timing capable of pressing the wedge projections 4a against the plate material 25 to form the long grooves 27 such that the stress is not propagated around during the bead formation. FIGS. 18A to 18C illustrates an exemplary processing method using a turret punch press apparatus. For example, the operation timing of the punch 2 and the die body 11 may be a timing as illustrated in FIGS. 18A to 18C. For example, as illustrated in FIG. 18B, the punch 2 and the die body 11 may be operated substantially at the same time such that the plate material 25 is sandwiched therebetween. Then, as illustrated in FIG. 18C, the punch 2 and the die body 11 may be separated substantially at the same time. For example, even though the wedge projections 4a do not bite completely into the plate material 25, the wedge projections 4a may be pressed against the plate material 25 at a timing capable of retarding the propagation of the stress generated in the plate material 25. The pitch P between the wedge projections 4a or other dimensions may be varied as necessary.

In the above-mentioned reinforcement of a chassis, the reinforcing portion 51a1 is formed while reducing the distortion or warpage for a sheet used in a chassis of an electronic device. Thereofore, the space saving, thinning and weight lightening of the chassis 51a, or rigidity may be enhanced. Since the warpage of the plate material 25 is suppressed during the reinforcement processing, variation in product quality in the production may be reduced. The NCT apparatus 100 may be used to perform a processing for obtaining a necessary strength in a necessary portion. Since the NCT apparatus 100 uses a versatile mold, the mold production cost and the number of mold production processes may be reduced. Distortion of the plate material may also be suppressed. By the above-described technique, reinforcement of a chassis may be achieved, or reinforcement of various parts or structures constituted by processing a plate material may also be achieved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A reinforcement method comprising:
pressing a punch against a plate material from an opposite side to a die body to form a reinforcing portion on the plate material,
wherein the punch includes a wedge projection which is provided in flank of a reinforcing portion forming portion extending along a relative movement direction of the die body and in parallel with the reinforcing portion forming portion, and is longer than a length of the relative movement direction of the die body.

2. The reinforcement method according to claim 1, wherein the reinforcing portion forming portion is groove-shaped, and a groove-shaped reinforcing portion along the relative movement direction of the die body is formed.

3. The reinforcement method according to claim 1, wherein the plate material is a chassis.

4. The reinforcement method according to claim 3, wherein the chassis is included in a server device.

5. A turret punch press apparatus, comprising:
a die body;
a reinforcing portion forming portion extending along a relative movement of the die body; and
a punch provided with a wedge projection which is provided in flank of the reinforcing portion forming portion and in parallel with the reinforcing portion forming portion, and is longer than a length of the relative movement direction of the die body to form a reinforcing portion on a plate material.

6. The turret punch press apparatus according to claim 5, wherein the punch includes:
a plate-like punch chip; and
a wedge chip embedded in the punch chip.

7. The turret punch press apparatus according to claim 6, wherein the wedge chip includes a first wedge chip and a second wedge chip, and
the first wedge chip and the second wedge chip are provided at both sides of the reinforcing portion forming portion along the relative movement direction of the die body respectively.
